(19) United States
(12) Patent Application Publication
(10) Pub. No.: US 2022/0042204 A1
(43) Pub. Date: Feb. 10, 2022

(54) Method of Manufacturing CZ Silicon Wafers

(71) Applicant: Infineon Technologies AG, Neubiberg (DE)

(72) Inventors: Hans-Joachim Schulze, Taufkirchen (DE); Helmut Oefner, Zorneding (DE)

(21) Appl. No.: 17/389,820

(22) Filed: Jul. 30, 2021

(30) Foreign Application Priority Data
Aug. 7, 2020 (DE) 102020120933.9

(51) Int. Cl. C30B 15/20; C30B 29/06; C30B 15/04

(52) U.S. Cl. CPC C30B 15/20; C30B 15/04; C30B 29/06

(57) ABSTRACT

A method of manufacturing CZ silicon wafers is proposed. The method includes extracting a CZ silicon ingot over an extraction time period from a silicon melt including dopants being predominantly n-type. The method further includes introducing boron into the CZ silicon ingot over at least part of the extraction time period by controlling a boron supply to the silicon melt by a boron source. The method further includes determining a specific resistivity, a boron concentration, and a carbon concentration along a crystal axis of the CZ silicon ingot. The method further includes slicing the CZ silicon ingot or a section of the CZ silicon ingot into CZ silicon wafers. The method further includes determining at least two groups of the CZ silicon wafers depending on at least two of the specific resistivity, the boron concentration, and the carbon concentration.

### TECHNICAL FIELD

The present disclosure is related to a method of manufacturing CZ (Czochralski) semiconductor wafers, in particular by grouping the CZ silicon wafers.

### BACKGROUND

In silicon devices, e.g. insulated gate bipolar transistors (IGBTs), diodes, insulated gate field effect transistors (IGFETs) such metal oxide semiconductor field effect transistors (MOSFETs), a number of requirements need to be met. Such requirements may depend upon specific application conditions. Typically, trade-offs between interrelated characteristics, e.g. high electrical breakdown voltage and low on-state resistance, have to be found.

As a typical base material for manufacturing a variety of such semiconductor devices, silicon wafers grown by the Czochralski (CZ) method, e.g. by the standard CZ method or by the magnetic CZ (MCZ) method or by the Continuous CZ (CCZ) method are used. In the Czochralski method, silicon is heated in a crucible to the melting point of silicon at around 1416° C. to produce a melt of silicon. A small silicon seed crystal is brought in contact with the melt. Molten silicon freezes on the silicon seed crystal. By slowly pulling the silicon seed crystal away from the melt, a crystalline silicon ingot is grown with a diameter in the range of one or several 100 mm and a length in the range of a meter or more. In the MCZ method, additionally an external magnetic field is applied to reduce an oxygen contamination level.

Growing of silicon with defined doping by the Czochralski method is complicated by segregation effects. The segregation coefficient of a dopant material characterizes the relation between the concentration of the dopant material in the growing crystal and that of the melt. Typically, dopant materials have segregation coefficients lower than one meaning that the solubility of the dopant material in the melt is larger than in the solid. This typically leads to an increase of doping concentration in the ingot with increasing distance from the seed crystal.

Since in Czochralski grown silicon ingots, depending upon application of the grown silicon, a tolerance range of doping concentration or specific resistance along the axial direction between opposite ends of the silicon ingot may be smaller than the variability of doping concentration or specific resistance caused by segregation effects during CZ growth, it is desirable to provide a method of manufacturing silicon wafers that allow for an improved yield of semiconductor devices of a target device specification based on the CZ semiconductor wafers.

### SUMMARY

An example of the present disclosure relates to a method of manufacturing CZ silicon wafers. The method includes extracting a CZ silicon ingot over an extraction time period from a silicon melt comprising dopants being predominantly n-type. The method further includes introducing boron into the CZ silicon ingot over at least part of the extraction time period by controlling a boron supply to the silicon melt by a boron source. The method further includes determining a specific resistivity, a boron concentration, and a carbon concentration along a crystal axis of the CZ silicon ingot. The method further includes slicing the CZ silicon ingot or a section of the CZ silicon ingot into CZ silicon wafers. The method further includes determining at least two groups of the CZ silicon wafers depending on at least two of the specific resistivity, the boron concentration, and the carbon concentration.

A further example of the present disclosure relates to a further method of manufacturing CZ silicon wafers. The method includes extracting a CZ silicon ingot over an extraction time period from a silicon melt comprising dopants being predominantly n-type. The method further includes introducing boron into the CZ silicon ingot over at least part of the extraction time period by controlling a boron supply to the silicon melt by a boron source. The method further includes determining a carbon concentration along a crystal axis of the CZ silicon ingot. The method further includes slicing the CZ silicon ingot or a section of the CZ silicon ingot into CZ silicon wafers. The method further includes determining at least two groups of the CZ silicon wafers depending on at least the carbon concentration.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of manufacturing CZ silicon wafers and together with the description serve to explain principles of the embodiments. Further embodiments are described in the following detailed description and the claims.

FIGS. 1 to 4 are schematic views for illustrating a method of manufacturing CZ silicon wafers.

### DETAILED DESCRIPTION

In the following detailed description, reference is made to the accompanying drawings, which form a part thereof and in which are shown by way of illustrations specific embodiments in which CZ silicon wafers may be manufactured. It is to be understood that other embodiments may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. A parameter y with a value of at least c reads as c≤y and a parameter y with a value of at most d reads as y≤d.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The terms “wafer”, “substrate”, “semiconductor body” or “semiconductor substrate” used in the following description may include any semiconductor-based structure that has a semiconductor surface.

For example, a method of manufacturing CZ silicon wafers may include extracting a CZ silicon ingot over an extraction time period from a silicon melt comprising dopants being predominantly n-type. The method may further include introducing boron into the CZ silicon ingot over at least part of the extraction time period by controlling a boron supply to the silicon melt by a boron source. The method may further include determining a specific resistivity, a boron concentration, and a carbon concentration along a crystal axis of the CZ silicon ingot. The method may further include slicing the CZ silicon ingot or a section of the CZ silicon ingot into CZ silicon wafers. The method may further include determining at least two groups of the CZ silicon wafers depending on at least two, e.g. two or all three, of the specific resistivity, the boron concentration, and the carbon concentration.

The CZ silicon ingot may be extracted by a growth system, for example. The growth system may include a crucible, e.g. a quartz crucible on a crucible support, e.g. a graphite susceptor, for example. The growth system may further include a heater, e.g. a radio frequency (RF) coil may surround the crucible, for example. The heater may be arranged at lateral sides and/or at a bottom side of the crucible, for example. The crucible may be rotated by a supporting shaft, for example.

The silicon melt comprising n-type dopants may be formed by melting a mixture of silicon material, e.g. a non-crystalline raw material such as polysilicon and n-type dopants such as phosphorus (P), antimony (Sb), arsenic (As) or any combination thereof, in the crucible by heating via the heater. The n-type dopants may already constitute or be part of the initial doping of the silicon material to be melted and/or may be added as a solid or gaseous dopant source material. For example, the solid dopant source material is a dopant source particle such as a dopant source pill. The dopant source material may have a predetermined shape such as a disc shape, spherical shape or a cubic shape. For example, the shape of the dopant source material may be adapted to a supply device such as a dispenser configured to supply the dopant source material to a silicon melt in the crucible.

For example, the dopant source material may include, in addition to the dopant material, a carrier material or a binder material. For example, the dopant source material may be quartz or silicon carbide (SiC) doped with the dopant material. For example, the dopant source material may be a highly doped silicon material such as a highly doped polysilicon material that is doped to a greater extent than the silicon raw material.

The CZ silicon ingot may be pulled out of the crucible containing the silicon melt by dipping a seed crystal into the silicon melt which is subsequently slowly withdrawn at a surface temperature of the melt just above the melting point of silicon. The seed crystal may be a single crystalline silicon seed mounted on a seed support rotated by a pull shaft. A pulling rate which typically is in a range of a few mm/min and a temperature profile influence a diameter of the CZ grown silicon ingot.

Boron may be introduced into the CZ silicon ingot over at least part of the extraction time period by turning on and/or off a boron supply to the silicon melt at least once during the extraction time period. A boron supply profile versus time may also include pulsed-shaped turn-on cycles, for example. For example, the boron supply may be off at the beginning of the extraction period, e.g. during the first extraction period. Thus, only unintentional boron doping, if any, e.g. boron doping by impurities in the raw materials, may occur. During the second extraction period, e.g. an extraction time period after the period where the boron supply may be off, the boron supply may be turned on at least once, for example. Turn on of boron supply may be triggered when the specific resistivity falls below a certain threshold value, for example.

For example, boron may be introduced into the CZ silicon ingot by adding boron to the molten silicon at a constant rate. The boron may be added to the silicon melt from a boron doped quartz material such as a boron doped quartz material supplied to the silicon melt by the supply device, for example. In addition or as an alternative, the boron may be added to the silicon melt from a boron carbide or from a boron nitride source material that may also be supplied to the silicon melt by the supply device.

For example, the boron may be added to the silicon melt from a boron doped crucible. The boron doped crucible may be formed by implanting boron into the crucible, for example. The boron may be implanted into the crucible by one or more tilted implants and/or by non-tilted implant. A distribution of tilt angle(s) may be used to adjust the amount of boron that is supplied to the silicon melt by dissolving a material of the crucible in the silicon melt, e.g. at a rate in the range of approximately 10 pm/hour in case of a crucible made of quartz. The boron may be implanted into the crucible at various energies and/or at various doses. Applying a thermal budget to the crucible by heating may allow for setting a retrograde profile of the boron in the crucible. Multiple implants at various energies and/or doses further allow for setting a profile of the boron into a depth of the crucible. Thus, a rate of adding boron into the silicon melt may be adjusted, i.e. by selection of implantation parameters the rate of the addition of boron can be varied and controlled in a well-defined manner. By way of example, the profile of boron in the crucible may be a retrograde profile. As an alternative or in addition to implanting boron into the crucible, boron may also be introduced into the crucible by another process, e.g. by diffusion from a diffusion source such as a solid diffusion source of boron, for example. As a further alternative or in addition to the above processes of introducing boron into the crucible, boron may also be introduced into the crucible in-situ, i.e. during formation of the crucible.

For example, the boron may be introduced into the silicon melt and/or the CZ silicon ingot from the gas phase, e.g. by supply of diborane (B₂H₆) via the supply device. According to an embodiment, supply of boron in the gas phase may occur via a supply of inert gas into the CZ growth system. According to another example, supply of boron in the gas phase may occur via one or more tubes, e.g. a quartz tube extending into the silicon melt. According to yet another example, supply of boron in the gas phase may occur via one or more tubes ending at a short distance to the silicon melt. The tubes may include one or more openings at an outlet, e.g. in the form of a showerhead, for example.

For example, a liner layer may be formed on the crucible for controlling diffusion of boron out of the crucible into the silicon melt. As an example, the liner layer may be formed of quartz and/or silicon carbide. According to an example, the liner layer may be dissolved in the silicon melt before boron included in the crucible gets dissolved in the silicon melt and serves as a dopant during the growth process of the silicon ingot. This allows for adjusting a point of time when boron is available in the silicon melt as a dopant to be introduced into the silicon ingot. The liner layer may also delay introduction of boron into the silicon melt by a time period that is required for diffusion of boron from the crucible through the liner layer and into the silicon melt.

For example, the boron supply may be controlled such that a rate of adding the boron to the silicon melt is altered. According to an example, altering the rate of adding the boron to the silicon melt may include altering at least one of size, geometry, and rate of delivery of particles including the boron. By way of example, the rate may be increased by increasing a diameter of the particles doped with the dopant material. As an additional or alternative measure, the rate of adding the boron to the silicon melt may be increased by increasing a speed of supplying the dopant source material into the silicon melt by the supply device. According to another example, altering the rate of adding the boron to the silicon melt may include altering a depth of a dopant source material dipped into the silicon melt. According to another example, altering the rate of adding the boron to the silicon melt may include altering a temperature of the dopant source material. By way of example, by increasing a temperature of the dopant source material, e.g. by heating, the amount of boron introduced into the silicon melt out of the dopant source material may be increased. The dopant source material may be doped with the boron. According to an example, doping of the dopant source material is carried out by one of in-situ doping, by a plasma deposition process through a surface of the dopant source material, by ion implantation through the surface of the dopant source material and by a diffusion process through the surface of the dopant source material. The dopant source material may be shaped as a bar, a cylinder, a cone or a pyramid, for example. The dopant source material may also be made of a plurality of separate dopant source pieces having one or a combination of different shapes. The depth of a part of the dopant source material that is dipped into the silicon melt may be changed by a puller mechanism. The puller mechanism holds the dopant source material, dips the dopant source material into the silicon melt and also pulls the dopant source material out of the silicon melt. A control mechanism may be configured to control the puller mechanism. The control mechanism may control the puller mechanism by wired or wireless control signal transmission, for example.

For example, altering the rate of adding the boron to the silicon melt may include altering a flow or partial pressure of a boron carrier gas, e.g. diborane (B2H6) when doping the silicon melt and/or the CZ silicon ingot with boron from the gas phase.

For example, the rate of adding the boron to the silicon melt and/or the CZ silicon ingot may be controlled depending on a length of the silicon ingot from the seed crystal to the silicon melt during growth.

According to an example, boron may be added prior to and/or during CZ growth by a p-dopant source material such as a p-dopant source pill. The p-dopant source material may have a predetermined shape such as a disc shape, spherical shape or a cubic shape. By way of example, the shape of the p-dopant source material may be adapted to the supply device such as a dispenser configured to supply the p-dopant source material to a silicon melt in the crucible. A time-dependent supply of a p-dopant into the silicon melt may be achieved by adjusting a profile of p-type dopant concentration into a depth of the p-dopant source material, for example by multiple ion implantations at different energies and/or by forming a liner layer surrounding the p-dopant source material for controlling dissolving of the p-dopant from the p-dopant source material into the silicon melt or for controlling the diffusion of the p-dopant out of the p-dopant source material into the silicon melt.

The specific resistivity of the silicon ingot may be determined along the crystal axis of the CZ silicon ingot, e.g. between opposite ends of the CZ silicon ingot, by any appropriate characterization technique, e.g. van der Pauw resistivity measurement or four point probe measurement. The boron concentration may be determined along the crystal axis of the CZ silicon ingot, e.g. between opposite ends of the CZ silicon ingot, by any appropriate characterization technique, e.g. Fourier-transform infrared spectroscopy, FTIR, Secondary ion mass spectrometry, SIMS, X-ray fluorescence spectroscopy, Photoluminescence spectroscopy, or by experience. The carbon concentration may be determined along the crystal axis of the CZ silicon ingot, e.g. between opposite ends of the CZ silicon ingot, by any appropriate characterization technique, e.g. Fourier-transform infrared spectroscopy, FTIR, Secondary ion mass spectrometry, SIMS, X-ray fluorescence spectroscopy, Photoluminescence spectroscopy, or by experience.

For example, the CZ silicon ingot may be formed by the magnetic CZ (MCZ) method which is carried out within a strong horizontal (HMCZ) or vertical (VMCZ) magnetic field. This serves to control the convection fluid flow, thereby allowing for a lower oxygen concentration and more homogeneous impurity distribution compared with wafers manufactured according to the standard CZ method. Slicing the CZ silicon ingot into the CZ silicon wafers may be carried out based on a wire saw and/or an inner diameter (ID) saw, for example. The CZ silicon ingot results from growing the crystal by the CZ growth method and removing the seed-end, i.e. the top and the tapered-end, i.e. the bottom by using a saw, for example an ID saw. These ends may be discarded or re-melted for re-use in future crystal growth processes. After cutting the ends off, the ingot may be cut into shorter sections in order to optimize the slicing operation. The ingot may also be sliced without being cut into shorter sections if the slicing equipment is capable of processing corresponding ingot dimensions.

By determining the at least two groups of the CZ silicon wafers depending on at least two, e.g. two or all three, of the specific resistivity, the boron concentration, and the carbon concentration an average value of a parameter of the CZ silicon wafers of each group differs among the first and second groups, and a tolerance of the parameter of the CZ silicon wafers of each group may be smaller than a tolerance of the parameter of the target specification. This may allow for an improved yield of the CZ silicon ingot. For example, the CZ silicon wafers may be divided into two, three, four or even more groups. By way of example, when dividing the group of the CZ silicon wafers into two groups, i.e. a first sub-group and a second sub-group, the CZ silicon wafers of the first group may include those wafers of the CZ silicon wafers having a boron doping smaller than the boron doping of the wafers of the second group.

For example, a boron concentration of each of the CZ silicon wafers of one of the at least two groups is smaller than 10¹⁴ cm⁻³, or smaller than 6.0×10¹³ cm⁻³, or smaller than 3.0×10¹³ cm⁻³, or smaller than 1.0×10¹³ cm⁻³, or smaller than 5.0×10¹² cm⁻ and a boron concentration of each of the CZ silicon wafers of another one of the at least two groups is larger than 10¹⁴ cm⁻³, or larger than 6.0×10¹³ cm⁻³, or larger than 3.0×10¹³ cm⁻³, or larger than 1.0×10¹³ cm⁻³, or larger than 5.0×10¹² cm⁻³. For example, the one of the at least two groups may include or consist of CZ silicon wafers having no intentional boron doping, e.g. wafers cut from such a part of the CZ silicon ingot where no boron has been intentionally introduced into the CZ silicon ingot as described in the examples above. The other one of the at least two groups may include or consist of CZ silicon wafers having intentional boron doping, e.g. wafers cut from such a part of the CZ silicon ingot where boron has been intentionally introduced into the CZ silicon ingot as described in the examples above.

For example, a carbon concentration of each of the CZ silicon wafers of one of the at least two groups may be smaller than 1×10¹⁵ cm⁻³, or smaller than 2.0×10¹⁵ cm⁻³, or smaller than 2.5×10¹⁵ cm⁻³, or smaller than 5×10¹⁵ cm⁻³. A carbon concentration of each of the CZ silicon wafers of another one of the at least two groups is larger than 1×10¹⁵ cm⁻³, or larger than 2.0×10¹⁵ cm⁻³, or larger than 2.5×10¹⁵ cm⁻³, or larger than 5×10¹⁵ cm⁻³. This may allow for grouping the CZ silicon wafers with respect to carrier lifetime, for example. For example, an end part of the CZ silicon ingot may not be part of the CZ silicon wafers of the at least two groups, e.g. because the carbon concentration in this part of the CZ silicon ingot may be larger than a certain threshold value.

For example, a length of the CZ silicon ingot may be at least 0.3 m.

For example, a diameter of the CZ silicon ingot may be at least 200 mm, or equal to or greater than 300 mm.

For example, the boron supply may be at least once turned on after extraction of at least part of the CZ silicon ingot. Thereby, at least a first section of the CZ silicon ingot may be formed with no intentional boron doping. The CZ silicon wafers cut from the first section may constitute one of the at least two groups of the CZ silicon wafers. The wafers of the first group may differ from the CZ silicon wafers of a second group or other groups by the boron concentration being smaller than a threshold value identified for distinguishing between intentional and unintentional boron doping. As an alternative or in addition, the wafers of the first group may differ from the CZ silicon wafers of a second or other groups by the carbon concentration being smaller than a threshold value identified for distinguishing between wafers having different carrier lifetime.

For example, the method may further include preparing a labeling configured to distinguish between the at least two groups of the CZ silicon wafers. The method may further include packaging the CZ silicon wafers of the at least two groups.

For example, the CZ silicon wafers of at least two groups of the CZ silicon wafers may be packaged in a same shipping case. For example, the labeling may distinguish between the at least two groups of the CZ silicon wafers by at least one of a position in the shipping case, or by a mark on the CZ silicon wafers. Positions in the shipping case housing wafers of the first group may be distinguished from other positions in the shipping case housing wafers of the second group or other groups by a marking on the case, for example different markings for the groups placed at the different positions in the shipping case or an adhesive label on the shipping case assigning the shipping case positions to wafers of the first or second group, respectively. In some other examples, the labeling distinguishes between the CZ silicon wafers of different groups by a mark on the CZ silicon wafers. In some examples, the mark is formed by using laser technology, for example to place a permanent and highly-readable mark on a surface of the wafers to allow traceability of the wafers at least up to semiconductor manufacturing processes that are carried out based on different process parameters for the semiconductor wafers of the at least two groups, respectively. By way of example, the semiconductor wafers of a first group of the at least two groups may be thinned to a different thickness than the semiconductor wafers a second group of the at least two groups based on the information gathered by analyzing the labeling.

For example, the CZ silicon wafers of at least two groups of the CZ silicon wafers may be packaged in separate shipping cases.

For example, controlling the boron supply by the boron source includes at least one of i) controlling at least one of size, geometry and rate of delivery of particles including boron, ii) controlling a flow or partial pressure of a boron carrier gas, iii) controlling an amount of a source material brought in contact with the silicon melt, e.g. by dipping into the silicon melt, and altering a temperature of the source material, wherein the source material is doped with boron. Further details on boron supply are described with reference to the examples above and below.

For example, the method may further include determining an oxygen concentration along the crystal axis of the CZ silicon ingot. For example, the method may further include determining the at least two groups depending on the oxygen concentration along the crystal axis of the CZ silicon ingot. For example, parts of the CZ silicon ingot at opposite ends of the CZ silicon ingot may not be part of the CZ silicon wafers of the at least two groups, e.g. because the oxygen concentration in these parts of the CZ silicon ingot may be larger than a threshold value. For example, an oxygen concentration of each of the CZ silicon wafers of one of the at least two groups may be smaller than 2.2×10¹⁷ cm⁻³, or smaller than 3.0×10¹⁷ cm⁻³, or smaller than 3.5×10¹⁷ cm⁻³. An oxygen concentration of each of the CZ silicon wafers of another one of the at least two groups may be larger than 2.2×10¹⁷ cm⁻³, or larger than 3.0×10¹⁷ cm⁻³, or larger than 3.5×10¹⁷ cm⁻³.

For example, the method may further include determining a carbon concentration along the crystal axis of the CZ silicon ingot. For example, the method may further include determining the at least two groups depending on the carbon concentration. For example, an end part of the CZ silicon ingot may not be part of the CZ silicon wafers of the at least two groups, e.g. because the carbon concentration in this part of the CZ silicon ingot may be larger than a threshold value.

A further example relates to a further method of manufacturing CZ silicon wafers. The method may include extracting a CZ silicon ingot over an extraction time period from a silicon melt comprising dopants being predominantly n-type. The method may further include introducing boron into the CZ silicon ingot over at least part of the extraction time period by controlling a boron supply to the silicon melt by a boron source. The method may further include determining a carbon concentration along a crystal axis of the CZ silicon ingot. The method may further include slicing the CZ silicon ingot or a section of the CZ silicon ingot into CZ silicon wafers. The method may further include determining at least two groups of the CZ silicon wafers depending on at least the carbon concentration. Determining the carbon concentration may include measuring the carbon concentration, e.g. as described with respect to the examples above.

The examples and features described above and below may be combined.

More details and aspects are mentioned in connection with the examples described above or below. Manufacturing the CZ silicon wafers may comprise one or more optional additional features corresponding to one or more aspects mentioned in connection with the proposed concept or one or more examples described above or below.

The aspects and features mentioned and described together with one or more of the previously described examples and figures, may as well be combined with one or more of the other examples in order to replace a like feature of the other example or in order to additionally introduce the feature to the other example. For example, exemplary details described with reference to the examples above, e.g. details on materials, functions, arrangements or dimensions of structural elements, correspondingly apply to the examples described further below with reference to the drawings.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. For example, the carbon concentration or the at least two of the specific resistivity or specific electric resistance, the boron concentration, and the carbon concentration may be determined along the crystal axis of the CZ silicon ingot before or after slicing the CZ silicon ingot or a section of the CZ silicon ingot into CZ silicon wafers. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

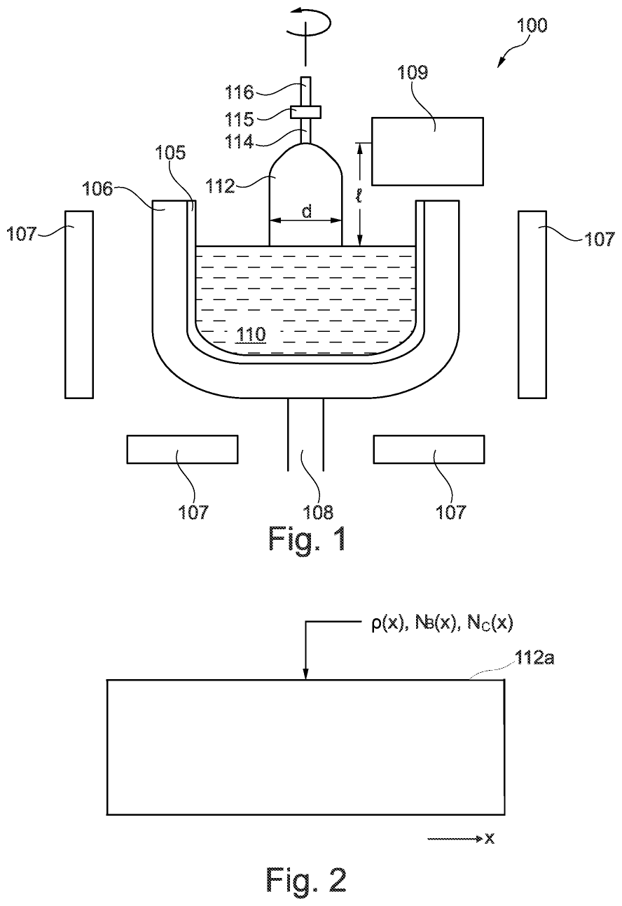

FIGS. 1 to 4 are schematic views for illustrating a method of manufacturing CZ silicon wafers.

FIG. 1 is a simplified view of a CZ growth system 100 for illustrating a method for manufacturing CZ silicon wafers. Functional and/or structural details described with reference to features in the examples described above likewise apply to the illustrated examples. The CZ growth system 100 includes a crucible 105, e.g. a quartz crucible on a crucible support 106, e.g. a graphite susceptor. A heater 107, e.g. a radio frequency (RF) coil surrounds the crucible. The heater 107 may be arranged at lateral sides and/or at a bottom side of the crucible 105. The crucible 105 may be rotated by a supporting shaft 108. A mixture of silicon material, e.g. a non-crystalline raw material such as polysilicon and an n-type dopant material such as phosphorus (P), antimony (Sb), arsenic (As) or any combination thereof is melted in the crucible by heating via the heater 107. The n-type dopant material may already constitute or be part of the initial doping of the silicon material to be melted and/or may be added as a solid or gaseous dopant source material. According to an example, the solid dopant source material is a dopant source particle such as a dopant source pill. The dopant source material may have a predetermined shape such as a disc shape, spherical shape or a cubic shape. By way of example, the shape of the dopant source material may be adapted to a supply device 109 such as a dispenser configured to supply the dopant source material to a silicon melt 110 in the crucible 105.

A CZ silicon ingot 112 is pulled out of the crucible 105 containing the silicon melt 110 by dipping a seed crystal 114 into the silicon melt 110 which is subsequently slowly withdrawn at a surface temperature of the melt just above the melting point of silicon. The seed crystal 114 is a single crystalline silicon seed mounted on a seed support 115 rotated by a pull shaft 116. A pulling rate which typically is in a range of a few mm/min and a temperature profile influence a diameter of the CZ grown silicon ingot 112.

Referring to the schematic view of FIG. 2, at least two of a specific resistivity ρ(x), or specific electric resistance, a boron concentration N_{B}(x), and a carbon concentration N_{C}(x) are determined along a crystal axis x of the CZ silicon ingot 112. The at least two of the specific resistivity ρ(x) and the boron concentration N_{B}(x) may be determined along the crystal axis x of the CZ silicon ingot before slicing the CZ silicon ingot or a section of the CZ silicon ingot into CZ silicon wafers. For example, the specific resistivity ρ(x), or specific electric resistance, and/or the boron concentration N_{B}(x), and/or the carbon concentration N_{C}(x) may be measured at a plurality of locations along the crystal axis x and be interpolated with respect to other locations along the crystal axis x. The at least two of a specific resistivity ρ(x), or specific electric resistance, a boron concentration N_{B}(x), and a carbon concentration N_{C}(x) may also be determined along the crystal axis of the CZ silicon ingot by experience. This may allow for avoiding measurements, for example. In some other examples, the at least two of a specific resistivity ρ(x), or specific electric resistance, a boron concentration N_{B}(x), and a carbon concentration N_{C}(x) may be determined along the crystal axis x of the CZ silicon ingot after slicing the CZ silicon ingot or a section of the CZ silicon ingot into CZ silicon wafers.

The CZ silicon ingot 112a results from growing the crystal 112 by the CZ growth method and removing the seed-end, i.e. the top and the tapered-end, i.e. the bottom by using a saw, for example an ID saw. These ends may be discarded or re-melted for re-use in future crystal growth processes. After cutting the ends off, the ingot may be cut into shorter sections in order to optimize the slicing operation. The ingot may also be sliced without being cut into shorter sections if the slicing equipment is capable of processing corresponding ingot dimensions.

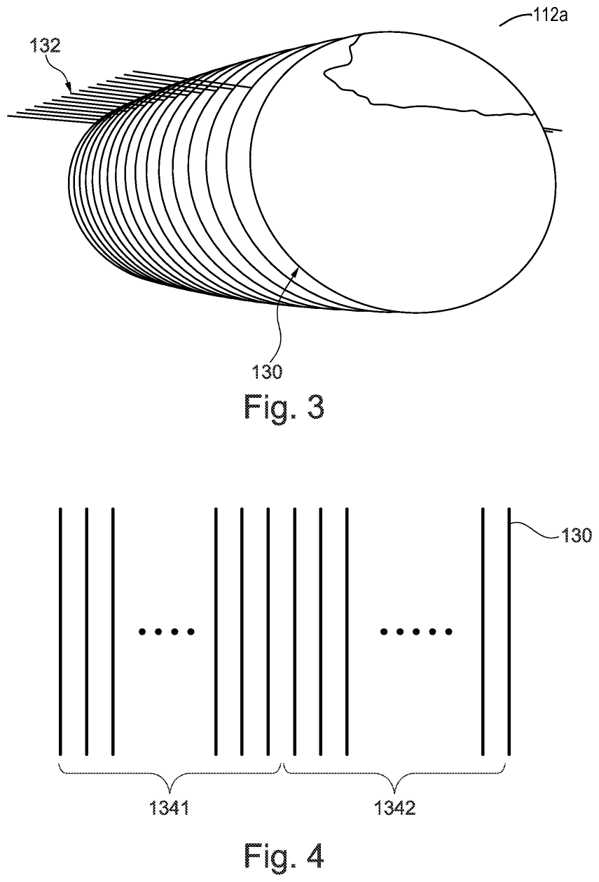

Referring to the schematic view of FIG. 3, the CZ silicon ingot 112a or a section of the CZ silicon ingot 112a is sliced into CZ silicon wafers 130. In the example illustrated in FIG. 3 the CZ silicon ingot is sliced into the CZ silicon wafers by using a wire saw 132. Any other suitable method for slicing the CZ silicon ingot 112 into the CZ silicon wafers 130, for example an ID saw, may also be applied.

Referring to the schematic view of FIG. 4, at least two groups, e.g. a first group 1341 and a second group 1342, of the CZ silicon wafers 130 are determined depending on at least two, e.g. two or all three, of the specific resistivity, the boron concentration or the carbon concentration. For example, the CZ silicon wafers of the first group 1341 may include no boron doping, or no intentional boron doping, and the CZ silicon wafers of the second group 1342 may include CZ silicon wafers having an intentional boron doping.

The CZ silicon wafers 130 may be processed based on process parameters that at least partly differ among the CZ silicon wafers 130 of the different groups, e.g. the first group 1341 and the second group 1342. Processing may include Front-end-of-line (FEOL) processes and Back-end-of-line (BEOL) processes. FEOL processes are the first processes in integrated circuit or discrete semiconductor fabrication, involving the formation of devices including transistors, capacitors, resistors, and more directly in the silicon wafer. BEOL processing involves a series of processes used to prepare integrated circuits for use. These processes include interconnects, wafer thinning, wafer dicing, inspection, die sort and final packaging. The devices in the silicon wafer may be interconnected to provide a desired electrical circuit functionality. Wires such as patterned metallization layers isolated by dielectric layers may be used to interconnect the individual devices.

In some examples, the CZ silicon wafers 130 of the different groups, e.g. the first group 1341 and the second group 1342, may be thinned to different target thicknesses. Wafer thinning is a process in which wafer material is removed from a back side of wafer, thereby producing a thinner wafer that allows for an adjustment of on-state resistance and heat dissipation behavior, for example. The process of thinning may be carried out by one or more processes such as back grinding in an automated back grinding machine based on computer-controlled grinding wheels, chemical and plasma etching processes, for example.

In some examples, the CZ silicon wafers 130 of the group, e.g. the first group 1341 or the second group 1342, having the larger mean resistivity may be thinned to a larger target thickness than the CZ silicon wafers 130 of the group having the smaller mean resistivity. For example, for an increase of the mean resistivity of the wafers in a sorted group by 5% to 10%, the thickness may be increased e.g. by 2 to 10 micrometers or by 3 to 8 micrometers. Thereby, a softness during switching of transistors formed in the wafers of the different sub-groups from an on-state into an off-state may be adapted to each other. Likewise, an avalanche breakdown robustness of transistors formed in the wafers of the different sub-groups may be adapted to each other.

Some examples may include forming an IGBT in the CZ silicon wafers 130, wherein dopants of a rear side emitter of the IGBT are implanted with different implant doses for silicon wafers of different groups. In some examples, the implant dose of the CZ silicon wafers 130 of the group having the larger mean resistivity is set larger (or smaller in some applications) than the implant dose of the CZ silicon wafers of the group having the smaller mean resistivity, for example by 2% to 20%, or by 4% to 8%. Thereby, a softness during switching of IGBTs formed in the wafers of the different groups from an on-state into an off-state may be adapted to each other. It may be useful to combine the adaption of the wafer thickness and the backside emitter doping e.g. by increasing the wafer thickness by 3 to 8 micrometers combined with an increase of the backside emitter implantation dose by more than 5%, or even more than 10%, or even more than 20%.

Some examples may include forming a transistor in the CZ silicon wafers 130, wherein dopants of a field stop zone of the transistor are implanted with different implant doses for silicon wafers of different groups, e.g. the first group 1341 or the second group 1342. When using proton irradiation for manufacturing of a field stop zone, the proton implantation dose or doses (when using multiple implantation energies) may be decreased (or increased in some applications) by more than 10% for an increase of the mean resistivity of the wafers in a sorted group e.g. by 5% to 10%. When using phosphorus or selenium implantation for formation of the field stop zone, the proton implantation dose or doses (when using multiple implantation energies) may be decreased by more than 3% for an increase of the mean resistivity of the wafers in a sorted group e.g. by 5% to 10%. Thereby, a rear side emitter efficiency of an IGBT and a transport factor of an FET or IGBT formed in the wafers of the different groups may be adapted to each other.

Some examples may include forming a transistor in the CZ silicon wafers 130, wherein a resistance of a gate resistor is formed based on different values for silicon wafers of different groups, e.g. the first group 1341 or the second group 1342. Thereby, a switching behavior of transistors formed in the wafers of the different sub-groups may be adapted to each other.

Another example may include forming a transistor in the CZ silicon wafers 130, wherein the threshold voltage for forming the channel is adjusted according to different concentrations of boron in a first group 1341 and a second group 1342 by adjusting dopant implantations into the wafers.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

What is claimed is:

1. A method of manufacturing CZ silicon wafers, the method comprising:
extracting a CZ silicon ingot over an extraction time period from a silicon melt comprising dopants being predominantly n-type;
introducing boron into the CZ silicon ingot over at least part of the extraction time period by controlling a boron supply to the silicon melt by a boron source;
determining a specific resistivity, a boron concentration, and a carbon concentration along a crystal axis of the CZ silicon ingot;
slicing the CZ silicon ingot or a section of the CZ silicon ingot into CZ silicon wafers; and
determining at least two groups of the CZ silicon wafers depending on at least two of the specific resistivity, the boron concentration, and the carbon concentration.

2. The method of the claim 1, wherein a boron concentration of each of the CZ silicon wafers of one of the at least two groups is smaller than 3.0×10¹³ cm⁻³, and wherein a boron concentration of each of the CZ silicon wafers of another one of the at least two groups is larger than 3.0×10¹³ cm⁻³.

3. The method of claim 1, wherein a carbon concentration of each of the CZ silicon wafers of one of the at least two groups is smaller than 1.5×10¹⁵ cm⁻³, and wherein a carbon concentration of each of the CZ silicon wafers of another one of the at least two groups is larger than 1.5×10¹⁵ cm⁻³.

4. The method of claim 1, wherein a length of the CZ silicon ingot is at least 0.3 m.

5. The method of claim 1, wherein a diameter of the CZ silicon ingot is at least 300 mm.

6. The method of claim 1, wherein determining the boron concentration and the carbon concentration along the crystal axis of the CZ silicon ingot comprises at least one of Fourier-transform infrared spectroscopy (FTIR), secondary ion mass spectrometry (SIMS), X-ray fluorescence spectroscopy, and photoluminescence spectroscopy.

7. The method of claim 1, wherein the boron supply is at least once turned on or increased after extraction of at least part of the CZ silicon ingot.

8. The method of claim 1, further comprising:
preparing a labeling configured to distinguish between the at least two groups of the CZ silicon wafers; and
packaging the CZ silicon wafers of the at least two groups.

9. The method of claim 8, wherein the labeling distinguishes between the at least two groups of the CZ silicon wafers by at least one of a position in a shipping case or by a mark on the CZ silicon wafers.

10. The method of claim 1, wherein the CZ silicon wafers of at least two groups of the CZ silicon wafers are packaged in a same shipping case.

11. The method of claim 1, wherein the CZ silicon wafers of at least two groups of the CZ silicon wafers are packaged in separate shipping cases.

12. The method of claim 1, wherein controlling the boron supply by the boron source comprises at least one of:
controlling at least one of size, geometry and rate of delivery of particles including boron;
controlling a flow or partial pressure of a boron carrier gas; and
controlling an amount of a source material brought in contact with the silicon melt and altering a temperature of the source material, wherein the source material is doped with boron.

13. The method of claim 1, further comprising:
determining an oxygen concentration along the crystal axis of the CZ silicon ingot.

14. The method of claim 13, further comprising:
determining the at least two groups depending on the oxygen concentration.

15. The method of claim 1, wherein an oxygen concentration of each of the CZ silicon wafers of one of the at least two groups is smaller than 2.2×10¹⁷ cm⁻³, and wherein an oxygen concentration of each of the CZ silicon wafers of another one of the at least two groups is larger than 2.2×10¹⁷ cm⁻³.

16. The method of claim 1, further comprising:
forming a transistor in the CZ silicon wafers,
wherein a resistance of a gate resistor is formed based on different values for silicon wafers of the at least two groups.

17. The method of claim 1, further comprising:
thinning the CZ silicon wafers of the at least two groups to different target thicknesses.

18. A method of manufacturing CZ silicon wafers, the method comprising:
extracting a CZ silicon ingot over an extraction time period from a silicon melt comprising dopants being predominantly n-type;
introducing boron into the CZ silicon ingot over at least part of the extraction time period by controlling a boron supply to the silicon melt by a boron source;
determining a carbon concentration along a crystal axis of the CZ silicon ingot;
slicing the CZ silicon ingot or a section of the CZ silicon ingot into CZ silicon wafers; and
determining at least two groups of the CZ silicon wafers depending on at least the carbon concentration.

19. The method of claim 18, wherein determining the carbon concentration includes measuring the carbon concentration.
